(19) United States
(12) Patent Application Publication
(10) Pub. No.: US 2018/0076030 A1
(43) Pub. Date: Mar. 15, 2018

(54) SiC FILM FORMING METHOD AND SiC FILM FORMING APPARATUS

(71) Applicant: TOKYO ELECTRON LIMITED, Tokyo (JP)

(72) Inventors: Kazuki YAMADA, Nirasaki City (JP); Masatoshi YAMATO, Nirasaki City (JP); Ryota IFUKU, Nirasaki City (JP); Shuji AZUMO, Nirasaki City (JP); Takashi FUSE, Nirasaki City (JP)

(21) Appl. No.: 15/697,355

(22) Filed: Sep. 6, 2017

(30) Foreign Application Priority Data
Sep. 15, 2016 (JP) 2016-180298

(51) Int. Cl. H01L 21/02; C23C 16/32

(52) U.S. Cl. CPC H01L 21/02529; C23C 16/325; H01L 21/02664; H01L 21/0262

(57) ABSTRACT

There is provided a SiC film forming method for forming a SiC film on a workpiece, including: a first step of forming a carbon film on the workpiece; and a second step of exposing the carbon film to a silicon-containing gas and causing silicon to be combined into the carbon film.

### CROSS-REFERENCE TO RELATED APPLICATION

This application is based upon and claims the benefit of priority from Japanese Patent Application No. 2016-180298, filed on Sep. 15, 2016, the entire contents of which are incorporated herein by reference.

### TECHNICAL FIELD

The present disclosure relates to a method and apparatus for forming a SiC film on a workpiece.

### BACKGROUND

In a manufacturing process of a semiconductor device, a film is embedded in an opening such as a trench or hole formed in a surface of a semiconductor substrate for various purposes. For example, in some instances a silicon oxide film or a silicon nitride film is embedded in a trench when separating elements from each other. Further, for example, a polysiloxane composition film is embedded in a hole in order to reverse a hole pattern.

In addition, along with recent miniaturization of semiconductor devices, a silicon carbide (SiC) film is desired as a film to be embedded in the above-described opening.

Various methods have been used as a SiC film forming method. For example, in a CVD (Chemical Vapor Deposition) method, raw material gases such as a carbon-containing gas and a silicon-containing gas are supplied into a reaction chamber while heating a substrate as a film formation target. The carbon-containing gas and the silicon-containing gas are thermally decomposed and are caused to react with each other on the substrate, whereby a SiC film is formed on the substrate.

Further, for example, in an ALD (Atomic Layer Deposition) method, a cycle including the supply of a silicon-containing precursor into a reaction chamber, the purging of the interior of the reaction chamber, the supply of a carbon-containing precursor into the reaction chamber and the purging of the interior of the reaction chamber is repeated while heating a substrate as a film formation target, whereby atomic layers are deposited one above another to form an SiC film on the substrate.

In addition, when a device is formed on a substrate as a film formation target, a film forming process should be performed at a low temperature, for example, 400 degrees C. or less in order to protect the device. However, in the above-described CVD method or ALD method, the film forming process is performed at a high temperature of 700 to 1,000 degrees C. or more. Therefore, the device formed on the substrate may be damaged.

As stated above, a method for appropriately forming a SiC film has not yet been established.

### SUMMARY

Some embodiments of the present disclosure provide a technique of appropriately forming a SiC film on a workpiece.

According to one embodiment of the present disclosure, there is provided a SiC film forming method for forming a SiC film on a workpiece, including: a first step of forming a carbon film on the workpiece; and a second step of exposing the carbon film to a silicon-containing gas and causing silicon to be combined into the carbon film.

According to another embodiment of the present disclosure, there is provided a SiC film forming apparatus for forming a SiC film on a workpiece, including: a carbon film forming part configured to form a carbon film on the workpiece; and a silicon infiltration part configured to expose the carbon film to a silicon-containing gas and to cause silicon to be combined into the carbon film.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a plan view schematically showing a configuration of a film forming apparatus according to an embodiment.

FIG. 2 is an explanatory view schematically showing a configuration of a silicon infiltration device.

FIG. 3 is a flowchart showing main steps of a film forming process.

FIGS. 4A to 4E are explanatory views showing states in the vicinity of a trench in respective steps of the film forming process.

FIGS. 5A to 5C are explanatory views showing states of a molecular structure of an amorphous carbon film in the respective steps of the film forming process.

FIG. 6 is a graph showing an XPS spectrum of silicon.

FIG. 7 is a flowchart showing main steps of a film forming process according to another embodiment.

FIG. 8 is a flowchart showing main steps of a film forming process according to another embodiment.

FIG. 9 is a plan view schematically showing a configuration of a film forming apparatus according to another embodiment.

### DETAILED DESCRIPTION

Hereinafter, embodiments of the present disclosure will be described with reference to the drawings. In the present specification and the drawings, the same reference numerals are given to constituent elements having substantially the same functions and configurations. Redundant explanation thereof will be omitted. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

As a result of the earnest research conducted by the present inventors, it was found that, when exposing a carbon film to a silicon-containing gas, silicon atoms is bonded to carbon atoms, thus causing silicon to be infiltrated into the carbon film.

### 1. Film Forming Apparatus

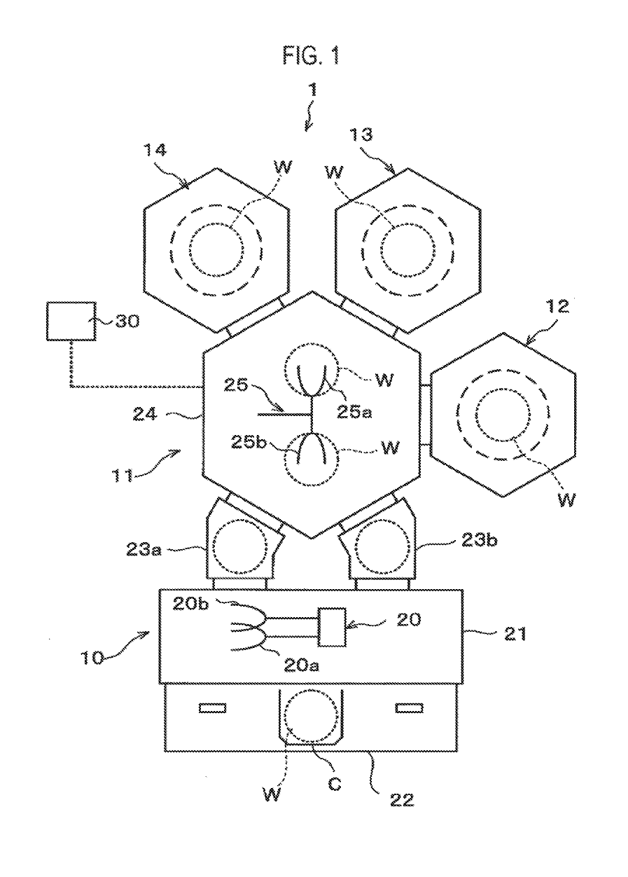

First, a configuration of a SiC film forming apparatus according to the present embodiment will be described. FIG. 1 is a plan view schematically showing a configuration of a film forming apparatus 1. The film forming apparatus 1 is configured to embed a SiC film in a trench formed in a semiconductor substrate W (hereinafter referred to as a substrate W) as a workpiece.

The film forming apparatus 1 includes a cassette station 10 for loading and unloading a substrate W into and from the film forming apparatus 1, a common transfer part 11 for transferring the substrate W, a carbon film forming device 12, a carbon etching device 13, and a silicon infiltration device 14.

The cassette station 10 includes a transfer chamber 21 in which a substrate transfer mechanism 20 for transferring the substrate W is installed. The substrate transfer mechanism 20 includes two transfer arms 20a and 20b for substantially horizontally holding the substrate W. The substrate transfer mechanism 20 is configured to transfer the substrate W while holding the substrate W by any one of the transfer arms 20a and 20b. At the side of the transfer chamber 21, there is a cassette mounting table 22 on which a cassette C capable of accommodating a plurality of substrates W step-by-step is mounted. In this embodiment, a plurality of, for example, three, cassettes C is shown to be mounted on the cassette mounting table 22.

The transfer chamber 21 and the common transfer part 11 are coupled to each other via two load lock devices 23a and 23b configured to be evacuated.

The common transfer part 11 includes a transfer part chamber 24 of a sealable structure formed so as to have, for example, a substantially polygonal shape (a hexagonal shape in the illustrated example) in a plan view. A substrate transfer mechanism 25 for transferring the substrate W is installed in the transfer part chamber 24. The substrate transfer mechanism 25 includes two transfer arms 25a and 25b for substantially horizontally holding the substrate W. The substrate transfer mechanism 25 is configured to transfer the substrate W while holding the substrate W by any of the transfer arms 25a and 25b.

The carbon film forming device 12, the carbon etching device 13, the silicon infiltration device 14 and load lock devices 23a and 23b are disposed outside the transfer part chamber 24 so as to surround the transfer part chamber 24. For example, the carbon film forming device 12, the carbon etching device 13, the silicon infiltration device 14 and the load lock devices 23a and 23b are arranged so as to be lined up counterclockwise in the named order in a plan view and so as to face the side surface portion of the transfer part chamber 24.

In the carbon film forming device 12, for example, an amorphous carbon film is formed as a carbon film on the substrate W. A well-known device, for example, a plasma CVD device or a thermal CVD device may be used as a film forming device for forming an amorphous carbon film. Any device may be used as long as the device can form an amorphous carbon film with a predetermined film thickness.

In the carbon etching device 13, the surplus of the amorphous carbon film formed by the carbon film forming device 12 is selectively etched and removed. A well-known device, for example, a plasma etching device or an oxidation device (a device for removing a carbon-containing film by an oxidation process) may be used as an etching device for removing a surplus amorphous carbon film. Any device may be used as long as the device can selectively etch a surplus amorphous carbon film.

In the silicon infiltration device 14, the amorphous carbon film is exposed to a silicon-containing gas so that silicon is introduced into the amorphous carbon film. A configuration of the silicon infiltration device 14 will be described later.

The film forming apparatus 1 described above is provided with a control part 30. The control part 30 is, for example, a computer, and includes a program storage part (not shown). In the program storage part, a program for controlling a film forming process in the film forming apparatus 1 is stored. This program is recorded in a computer-readable storage medium such as, for example, a computer-readable hard disk (HD), a flexible disk (FD), a compact disk (CD), a magneto-optical disk (MO), a memory card or the like. The program may be installed in the control part 30 from the storage medium.

### 2. Silicon Infiltration Device

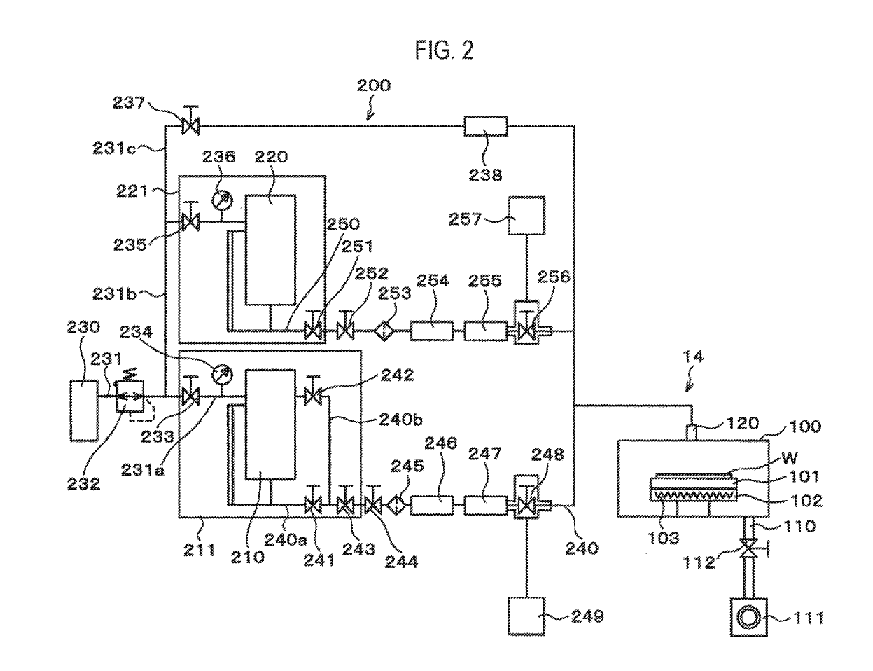

Next, a configuration of the aforementioned silicon infiltration device 14 will be described. FIG. 2 is an explanatory view schematically showing the configuration of the silicon infiltration device 14.

The silicon infiltration device 14 includes a processing container 100 whose interior is sealable. A loading/unloading port (not shown) through which the substrate W is loaded and unloaded is formed in a side surface of the processing container 100.

A mounting table 101 for mounting and holding the substrate W thereon is installed inside the processing container 100. Furthermore, a heating plate 102 is installed in the side of a lower surface of the mounting table 101. The heating plate 102 incorporates a heater 103 that generates heat when electric power is supplied thereto. The substrate W is heated to a predetermined temperature by the heater 103. Lift pins (not shown) for supporting the substrate W from below and raising and lowering the substrate W may be installed below the heating plate 102.

An exhaust pipe 110 for exhausting the interior of the processing container 100 is connected to the bottom surface of the processing container 100. The exhaust pipe 110 communicates with a vacuum pump 111 that evacuates the internal atmosphere of the processing chamber 100 to reduce the pressure. In addition, a valve 112 is installed in the exhaust pipe 110.

A supply pipe 120 for supplying a silicon-containing gas, water vapor and a nitrogen gas toward the inside of the processing container 100 is connected to a ceiling surface of the processing container 100. The supply pipe 120 communicates with a gas supply device 200 for supplying the silicon-containing gas, the water vapor and the nitrogen gas into the processing container 100.

The gas supply device 200 includes a silicon tank 210 for storing a silicon-containing liquid therein. As the silicon-containing liquid, for example, HMDS (substance name: bis (trimethylsilyl) amine, molecular formula: [(CH₃)₃Si]₂NH) is used. The silicon tank 210 is accommodated, for example, inside a storage compartment 211.

Further, the gas supply device 200 includes a water tank 220 for storing water therein. The water tank 220 is accommodated, for example, inside a storage compartment 221.

The silicon-containing liquid stored in the silicon tank 210 and the water stored in the water tank 220 are forcibly fed by the nitrogen gas, respectively. To do this, a nitrogen gas supply source 230 for storing the nitrogen gas is installed at the upstream side of the silicon tank 210 and the water tank 220. A regulator 232 for forcibly feeding the nitrogen gas is installed in a supply pipe 231 connected to the nitrogen gas supply source 230. The nitrogen gas supply source 230 and the regulator 232 are installed in a common path to the silicon tank 210 and the water tank 220. The supply pipe 231 is branched at the downstream side of the regulator 232 into a first supply pipe 231a connected to the silicon tank 210 and a second supply pipe 231b connected to the water tank 220. A valve 233 and a pressure gauge 234 are installed in the first supply pipe 231a sequentially from the upstream side. In addition, a valve 235 and a pressure gauge 236 are installed in the second supply pipe 231b sequentially from the upstream side.

At the downstream side of the regulator 232, the supply pipe 231 is further branched into a third supply pipe 231c in addition to the first supply pipe 231a and the second supply pipe 231b. The third supply pipe 231c is connected to the supply pipe 120 mentioned above. A valve 237 and a mass flow controller 238 are installed in the third supply pipe 231c sequentially from the upstream side. A nitrogen gas is supplied from the nitrogen gas supply source 230 to the inside of the processing container 100 via the third supply pipe 231c and the supply pipe 120. The nitrogen gas is used for purging the inside of the processing container 100 as described later.

Two supply pipes 240a and 240b are connected to the downstream side of the silicon tank 210. The lower supply pipe 240a is connected to the bottom surface of the silicon tank 210. A valve 241 is installed in the lower supply pipe 240a. The upper supply pipe 240b is connected to the upper side surface of the silicon tank 210. A valve 242 is installed in the upper supply pipe 240b. These supply pipes 240a and 240b merge at the downstream side of the valves 241 and 242 to constitute a supply pipe 240. The supply pipe 240 is further connected to the supply pipe 120 described above. The silicon-containing liquid is stored in the silicon tank 210. The silicon-containing liquid flows out from either the lower supply pipe 240a or the upper supply pipe 240b.

A valve 243, a valve 244, a filter 245, a vaporizer 246, a mass flow controller 247 and a valve 248 are installed in the supply pipe 240 sequentially from the upstream side. The valve 243 is installed inside the storage compartment 211, and the valve 244 is installed outside the storage compartment 211. This makes it possible to open and close the valves either inside or outside the storage compartment 211. The filter 245 removes particles existing in the silicon-containing liquid. In addition, a discharge pipe (not shown) for discharging bubbles generated in the silicon-containing liquid may be installed in the filter 245. The vaporizer 246 vaporizes the liquid-phase silicon-containing liquid and converts it into a gaseous silicon-containing gas. The mass flow controller 247 controls a flow rate of the silicon-containing gas. A temperature controller 249 is installed in the valve 248. The temperature of the silicon-containing gas passing through the valve 248 is adjusted to a predetermined temperature by the temperature controller 249.

A supply pipe 250 for supplying water is connected to the bottom surface of the water tank 220. The supply pipe 250 is connected to the aforementioned supply pipe 120. That is to say, the third supply pipe 231c from the nitrogen gas supply source 230, the supply pipe 240 from the silicon tank 210 and the supply pipe 250 from the water tank 220 are merged and connected to the supply pipe 120.

A valve 251, a valve 252, a filter 253, a vaporizer 254, a mass flow controller 255 and a valve 256 are installed in the supply pipe 250 sequentially from the upstream side. The valve 251 is installed inside the storage compartment 221, and the valve 252 is installed outside the storage compartment 221. This makes it possible to open and close the valves either inside or outside the storage compartment 221. The filter 253 removes particles existing in the water. A discharge pipe (not shown) for discharging air bubbles generated in the water may be installed in the filter 253. The vaporizer 254 vaporizes the liquid-phase water and converts it into a gaseous water vapor. The mass flow controller 255 controls a flow rate of the water vapor. A temperature controller 257 is installed in the valve 256. The temperature of the water vapor passing through the valve 256 is adjusted to a predetermined temperature by the temperature controller 257.

### 3. Film Forming Method

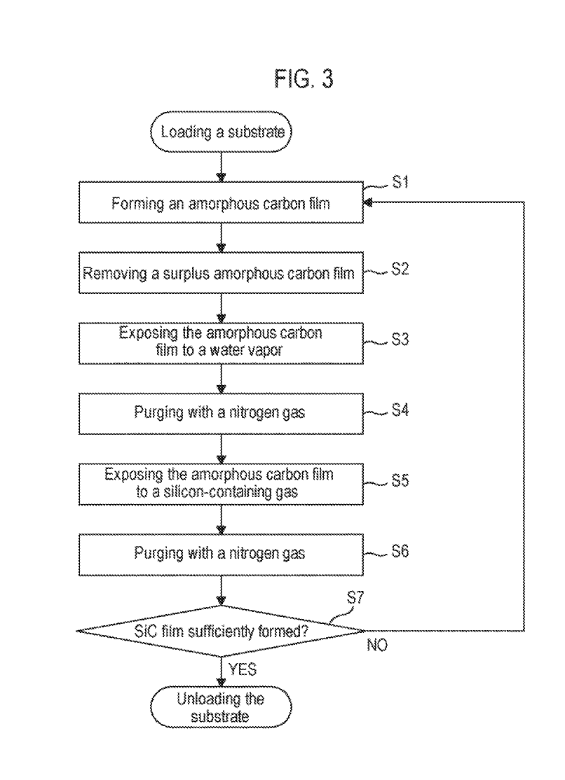

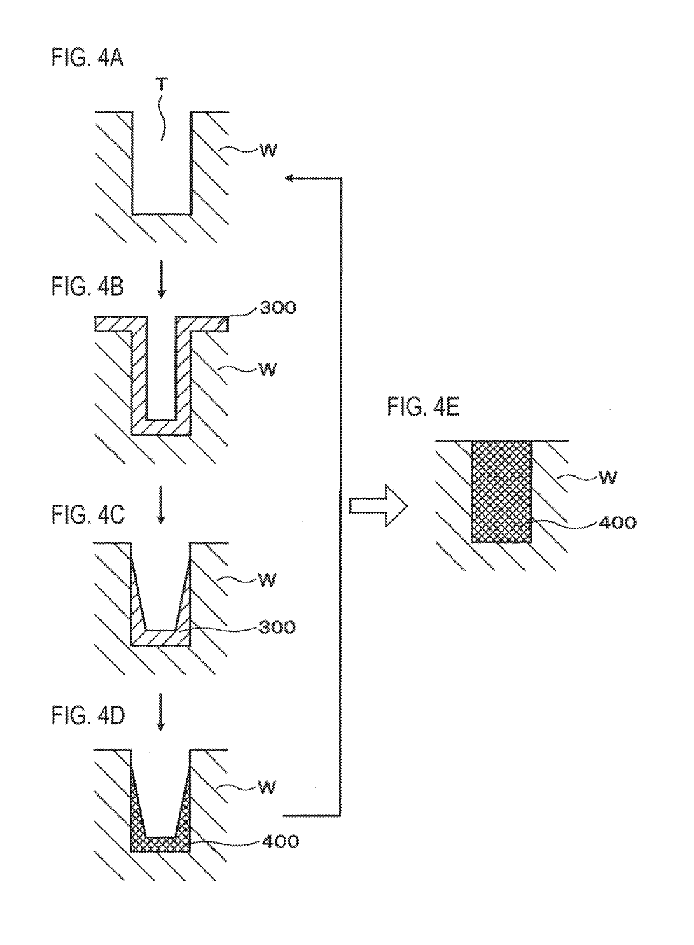

Next, a SiC film forming process performed using the film forming apparatus 1 configured as above will be described. In the present embodiment, as a film forming process, a SiC film is embedded in a trench of the substrate W. FIG. 3 is a flowchart showing an example of main steps of such a film forming process. FIGS. 4A to 4E are explanatory views showing states in the vicinity of the trench in the respective steps of the film forming process. In order to facilitate a clear understanding of the technique, one trench T is shown in FIG. 4A among a plurality of trenches formed in substrate W.

First, a cassette C containing a plurality of substrates W is loaded into the cassette station 10 of the film forming apparatus 1 and is mounted on the cassette mounting table 22. Thereafter, one substrate W is taken out from the cassette C by the substrate transfer mechanism 20 and is loaded into the load lock device 23a. Once the substrate W is loaded into the load lock device 23a, the interior of the load lock device 23a is hermetically sealed and depressurized. Thereafter, the interior of the load lock device 23a is brought into communication with the interior of the transfer part chamber 24 kept in a depressurized state (for example, in a substantially vacuum state) with respect to the atmospheric pressure. Then, the substrate W is unloaded from the load lock device 23a by the substrate transfer mechanism 25 and is loaded into the transfer part chamber 24.

The substrate W loaded into the transfer part chamber 24 is then transferred to the carbon film forming device 12 by the substrate transfer mechanism 25. In the carbon film forming device 12, an amorphous carbon film 300 is formed on the substrate W as shown in FIG. 4B (step S1 in FIG. 3). At this time, the amorphous carbon film 300 is formed at the same film thickness on the surface of the substrate W, the side surfaces of the trench T and the bottom surface of the trench T.

Thereafter, the substrate W is transferred to the carbon etching device 13 by the substrate transfer mechanism 25. In the carbon etching device 13, the surplus amorphous carbon film 300 is removed as shown in FIG. 4C (step S2 in FIG. 3). Specifically, the amorphous carbon film 300 formed on the surface of the substrate W and the amorphous carbon film 300 formed on the side surfaces of the upper portion of the trench T are selectively etched and removed.

Thereafter, the substrate W is transferred to the silicon infiltration device 14 by the substrate transfer mechanism 25. The substrate W loaded into the silicon infiltration device 14 is mounted on the mounting table 101. Then, the interior of the processing container 100 is depressurized to a predetermined degree of vacuum by operating the vacuum pump 111. Further, the substrate W is heated to a predetermined temperature, for example, 50 degrees C. to 400 degrees C., by the heater 103. The predetermined temperature of the substrate W is maintained during the process (steps S3 to S7).

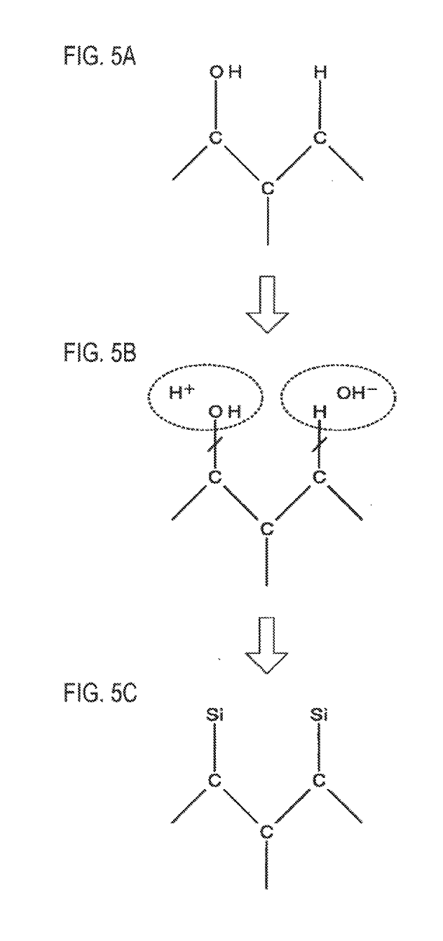

Thereafter, the water vapor of a predetermined temperature, for example, 50 to 400 degrees C., is supplied from the water tank 220 to the processing container 100. Then, the amorphous carbon film 300 formed on the substrate W is exposed to the water vapor (step S3 in FIG. 3). As shown in FIG. 5A, the amorphous carbon film 300 formed in steps S1 and S2 has a CH group and a COH group. When the amorphous carbon film 300 is exposed to the water vapor in step S3, as shown in FIG. 5B, the bond of the CH group is broken, and H⁺ of the CH group and OH⁻ in the water vapor undergo dehydration condensation. Likewise, the bond of the CH group is also broken, and OH⁻ of the COH group and H⁺ in the water vapor undergo dehydration condensation.

Thereafter, a nitrogen gas is supplied from the nitrogen gas supply source 230 toward the processing container 100 via the third supply pipe 231c and the supply pipe 120. Then, the interior of the processing container 100 is purged with the nitrogen gas (step S4 in FIG. 3). After the purging, the vacuum pump 111 is operated to depressurize the interior of the processing container 100 to a predetermined degree of vacuum.

Thereafter, a silicon-containing gas of a predetermined temperature, for example, 50 to 400 degrees C., is supplied from the silicon tank 210 toward the processing container 100. Then, the amorphous carbon film 300 formed on the substrate W is exposed to the silicon-containing gas (step S5 in FIG. 3). Since the bond of the CH group and the bond of the COH group are broken as shown in FIG. 5B, in step S5, silicon (Si) in the silicon-containing gas is bonded to C of the CH group or the COH group as shown in FIG. 5C. In other words, H of the CH group is substituted with Si, and OH of the COH group is substituted with Si. In this way, silicon is introduced into the amorphous carbon film 300. As the infiltration of silicon proceeds sufficiently, the amorphous carbon film 300 is modified into a SiC film 400 as shown in FIG. 4D, and the SiC film 400 is formed in the trench T.

As described above, the interior of the processing container 100 is depressurized to a predetermined degree of vacuum before step S5. Thus, the silicon-containing gas can be sufficiently supplied into the processing container 100 in step S5. This enables silicon to be sufficiently introduced into the amorphous carbon film 300.

Thereafter, the nitrogen gas is supplied from the nitrogen gas supply source 230 toward the processing container 100 via the third supply pipe 231c and the supply pipe 120. Then, the interior of the processing container 100 is purged with the nitrogen gas (step S6 in FIG. 3).

By repeating the above steps S1 to S6 and sufficiently forming the SiC film 400, the SiC film 400 is completely embedded in the trench T as shown in FIG. 4E (step S7 in FIG. 3). In step S7, according to a predetermined recipe, whether the SiC film 400 is completely embedded in the trench T may be determined. For example, it is only necessary to create a recipe in which the SiC film 400 is formed by performing the cycle of steps S1 to S6 n number of times where it is predetermined that the SiC film 400 is completely embedded in the trench T at the n^{th} time. Alternatively, whether or not the SiC film 400 is completely embedded in the trench T may be inspected separately. Although the inspection method is arbitrary, for example, the inspection may be performed by an optical system or may be performed using an electron microscope.

Thereafter, the substrate W is returned into the transfer part chamber 24 again by the substrate transfer mechanism 25. Then, the substrate W is transferred to the substrate transfer mechanism 20 via the load lock device 23b and is stored in the cassette C. Thereafter, the cassette C with the substrate W accommodated therein is unloaded from the film forming apparatus 1. In this way, a series of film forming processes is completed.

According to the above-described embodiment, in step 5, the amorphous carbon film 300 is exposed to the silicon-containing gas so that silicon can be introduced into the amorphous carbon film 300. Therefore, the SiC film 400 can be appropriately embedded in the trench T. In addition, the SiC film 400 can be formed by a low-temperature process of, for example, 400 degrees C. or less. Thus, even if a device is formed on the substrate W, it is possible to limit damage to the device. Accordingly, the film forming method of the present disclosure can be applied to various manufacturing processes of a semiconductor device.

Further, the amorphous carbon film 300 formed in step S1 has a CH group and a COH group, and the amorphous carbon film 300 is exposed to the water vapor in step S3. Therefore, the bond of the CH group and the bond of the COH group are broken by the water vapor. Thus, Si is easily bonded to the cut C in step S5, and silicon is more likely to be introduced into the amorphous carbon film 300.

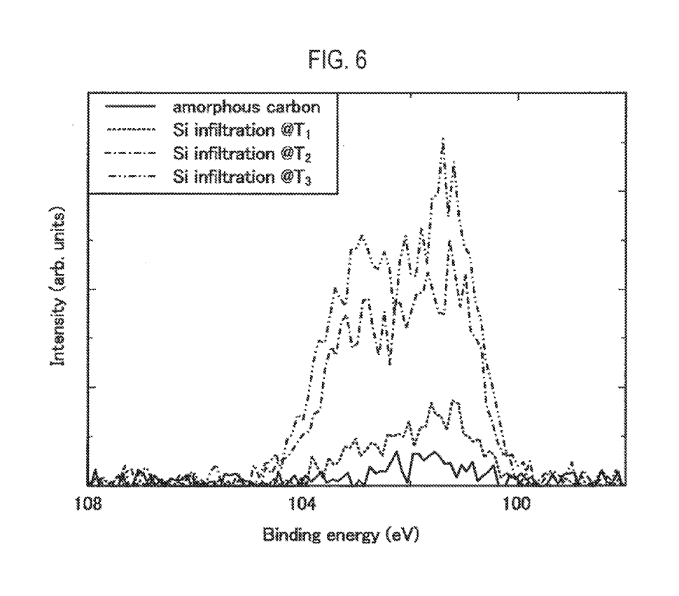

In this regard, the present inventors investigated the relationship between the temperature of the substrate W and the infiltration amount of silicon. FIG. 6 shows the XPS spectrum of silicon for four amorphous carbon films using X-ray photoelectron spectroscopy (XPS). In FIG. 6, the horizontal axis represents the binding energy and the vertical axis represents the intensity of XPS spectrum of silicon. The four amorphous carbon films are: 1. an amorphous carbon film not supplied with silicon (solid line in the figure); 2. an amorphous carbon film supplied with silicon at a substrate temperature T1 (dotted line in the figure); 3. an amorphous carbon film supplied with silicon at a substrate temperature T2 (one-dot chain line in the figure); and 4. an amorphous carbon film supplied with silicon at a substrate temperature T3 (two-dot chain line in the figure). The temperature of the substrate W is T1<T2<T3. T3 is the highest. Referring to FIG. 6, it can be seen that the higher the temperature of the substrate W, the greater the amount of silicon being introduced.

In this respect, in the present embodiment, the substrate W is heated to a predetermined temperature in step S5. It is therefore possible to further promote the bonding of C and Si.

Further, according to the above-described embodiment, by controlling the temperature of the substrate W in step S5 as described above, it is possible to control the amount of silicon being introduced into the amorphous carbon film 300. It is also possible to control the amount of silicon being introduced by controlling the number of cycles of steps S1 to S6. Accordingly, it is possible to control the Si/C ratio in the SiC film 400.

In addition, the film thickness of the SiC film 400 can also be controlled by controlling the film thickness of the amorphous carbon film 300 in step S1.

Since the Si/C ratio and the film thickness of the SiC film 400 can be appropriately controlled in this way, even when removing the SiC film 400 in a subsequent step performed outside the film forming apparatus 1, it is possible to easily peel the SiC film 400 from the substrate W. For example, if the upper layer portion of the SiC film 400 is formed of a SiC layer having appropriate properties and the lower layer portion thereof is left as the amorphous carbon film 300, the SiC film 400 can be easily peeled from the substrate W by wet processing. In this respect, the SiC film formed by the conventional method is a crystalline film and cannot be easily peeled from the substrate W. Accordingly, the present disclosure is extremely useful from such a viewpoint.

Further, in the film forming apparatus 1 of the present embodiment, the carbon film forming device 12, the carbon etching device 13 and the silicon infiltration device 14 are installed as individual apparatuses. Therefore, processing conditions can be easily adjusted in the respective devices, and processes can be performed under optimum conditions. In addition, it is possible to simplify the configurations of the respective devices 12, 13 and 14. Moreover, the maintenance of the respective devices 12, 13 and 14 can be performed with ease.

### 4. Other Embodiments

Next, other embodiments of the present disclosure will be described.

### 4-1. Other Embodiments of the Film Forming Method

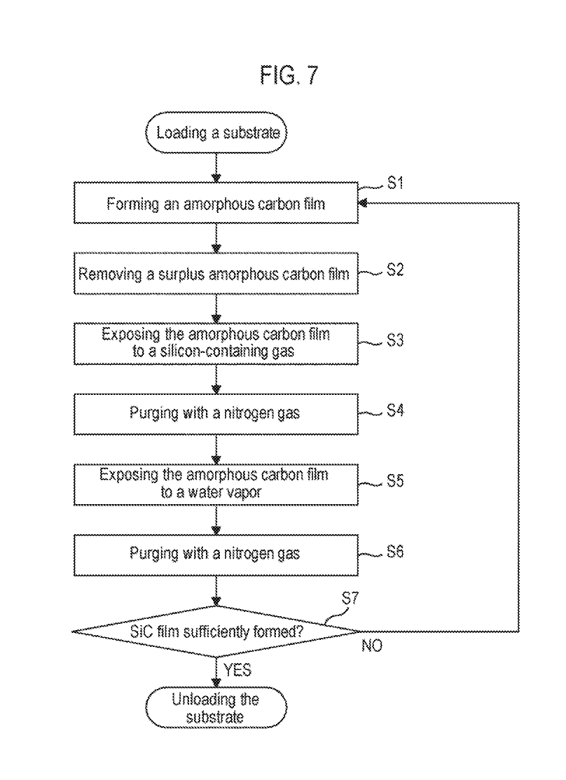

In the film forming method of the above-described embodiment, the exposure to the silicon-containing gas in step S5 is performed after the exposure to the water vapor in step S3. However, the order thereof may be reversed. In such a case, as shown in FIG. 7, the amorphous carbon film 300 is exposed to the silicon-containing gas in step S3. By doing so, Si in the silicon-containing gas is replaced by H of the CH group or OH of the COH group, and C and Si are bonded to each other. Then, silicon is introduced into the amorphous carbon film 300. Thereafter, purging is performed with a nitrogen gas in step S4 and, then, the amorphous carbon film 300 is exposed to the water vapor in step S5. By doing so, the bonding between C and Si is further promoted. Thus, the SiC film 400 is formed in the trench T.

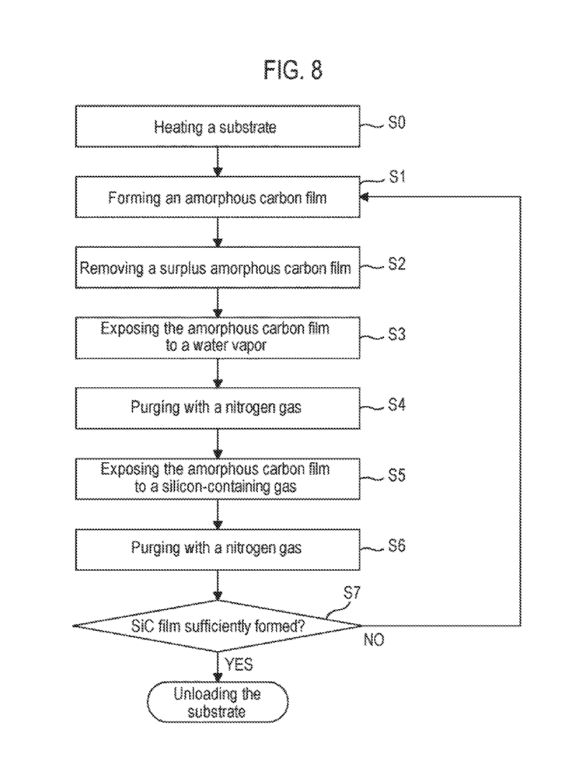

In the film forming method of the above-described embodiment, as shown in FIG. 8, the substrate W may be heated to a predetermined temperature, for example, 50 to 400 degrees C., before forming the amorphous carbon film 300 in step S1 (step S0 in FIG. 8). In such a case, the subsequent steps S1 to S6 can be appropriately performed. Further, in step S0, it is preferable to evacuate the process space of the substrate W and to depressurize the process space to a predetermined degree of vacuum. By performing the evacuation in this way, it is possible to appropriately and efficiently perform the heating of the substrate W. As a result, the SiC film can be appropriately formed.

### 4-2. Other Embodiments of the Film Forming Apparatus

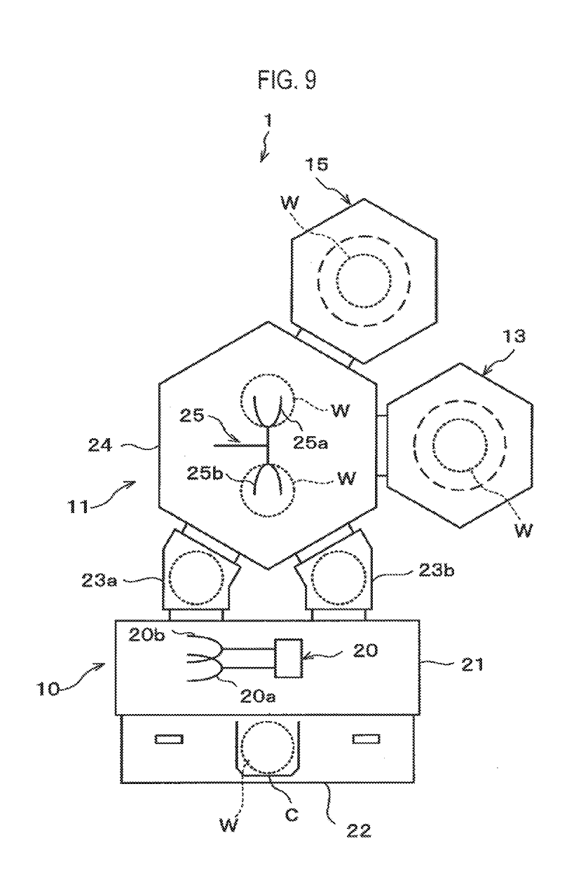

In the film forming apparatus 1 of the above-described embodiment, the carbon film forming device 12, the carbon etching device 13 and the silicon infiltration device 14 are individually installed. However, as shown in FIG. 9, the carbon film forming device 12 and the carbon etching device 13 may be configured as a single carbon processing device 15. In this case, in the single carbon processing device 15, the formation of the amorphous carbon film 300 and the removal of the surplus amorphous carbon film 300 are successively performed.

Although not shown, the carbon film forming device 12, the carbon etching device 13 and the silicon infiltration device 14 may be configured as a single device. In such a case, the formation of the amorphous carbon film 300, the removal of the surplus amorphous carbon film 300 and the infiltration of silicon into the amorphous carbon film 300 are successively performed in one device.

Further, for example, when such a successive process is performed by the single device, a rotary table capable of mounting a plurality of substrates W thereon may be installed in the single device. More specifically, a mechanism for forming the amorphous carbon film 300 may be installed at a position P1 where the rotary table is rotated, a mechanism for removing the surplus amorphous carbon film 300 may be installed at a position P2, and a mechanism for causing silicon to be infiltrated into the amorphous carbon film 300 may be installed at a position P3. In such a case, the rotary table is rotated and the substrate W is disposed at the position P1 to form the amorphous carbon film 30X). The rotary table is further rotated and the substrate W is disposed at the position P2 to remove the surplus amorphous carbon film 300. The rotary table is further rotated and the substrate W is disposed at the position P3 to cause silicon to be infiltrated into the amorphous carbon film 300.

Further, in the above-described embodiment, a so-called single wafer process of processing one substrate W by the single device is performed. However, a so-called batch process of processing a plurality of substrates W at the same time may be performed. For example, in the case where the carbon film forming device 12, the carbon etching device 13 and the silicon infiltration device 14 are configured as a single device, the formation of the amorphous carbon film 300, the removal of the surplus amorphous carbon film 300 and the infiltration of silicon into the amorphous carbon film 300 are successively performed by the batch process for the plurality of substrates W.

As described above, the apparatus for realizing the SiC film forming method according to the present disclosure is not particularly limited. Various apparatus configurations may be adopted.

### 4-3. Other Embodiments

While in the above-described embodiment, the case where silicon is infiltrated into the amorphous carbon film 300 has been described, the film to be infiltrated with silicon may be another carbon film. The carbon film has at least carbon atoms. By applying the film forming method of the present disclosure, it is possible to bond silicon atoms to carbon atoms and to cause silicon to be infiltrated into the carbon film.

Further, in the above-described embodiment, there has been described the case where the SiC film is embedded in the trench T formed in the substrate W. However, the present disclosure can be applied in other ways. For example, a SiC film may be embedded in a hole formed in the substrate W using the film forming method of the present disclosure. Moreover, by using the film forming method of the present disclosure, a SiC film which is a flat film may be formed on the substrate W. Such a SiC film as a flat film can be used for various applications such as, for example, an etching stopper material, an anti-reflection film and the like.

According to the present disclosure in some embodiments, it is possible to appropriately form a SiC film on a workpiece by exposing a carbon film to a silicon-containing gas and allowing silicon to infiltrate into the carbon film.

Although the preferred embodiments of the present disclosure have been described with reference to the accompanying drawings, the present disclosure is not limited to such examples. It will be apparent to those skilled in the art that various modifications or changes can be conceived within the scope of the spirit of the present disclosure described in the claims. It is to be understood that such modifications or changes fall within the technical scope of the present disclosure.

What is claimed is:

1. A SiC film forming method for forming a SiC film on a workpiece, comprising:
a first step of forming a carbon film on the workpiece; and
a second step of exposing the carbon film to a silicon-containing gas and causing silicon to be combined into the carbon film.

2. The method of claim 1, wherein the second step includes:
exposing the carbon film to a water vapor, and
alternately performing the exposing the carbon film to a silicon-containing gas and the exposing the carbon film to a water vapor.

3. The method of claim 1, wherein the carbon film formed in the first step includes at least a CH group or a COH group.

4. The method of claim 1, further comprising: before the second step, depressurizing a space in which the workpiece is processed and heating the workpiece to a predetermined temperature,
wherein the second step includes supplying the silicon-containing gas to the space, and exposing the carbon film to the silicon-containing gas.

5. The method of claim 1, wherein the first step and the second step are repeatedly performed in the named order to form a SiC film having a predetermined film thickness.

6. The method of claim 1, further comprising: forming an opening in the workpiece,
wherein the first step includes forming the carbon film at least inside the opening,
the method further comprising: after the first step and before the second step, removing the carbon film existing in a region other than the opening.

7. A SiC film forming apparatus for forming a SiC film on a workpiece, comprising:
a carbon film forming part configured to form a carbon film on the workpiece; and
a silicon infiltration part configured to expose the carbon film to a silicon-containing gas and to cause silicon to be combined into the carbon film.
